(19) United States
(12) Patent Application Publication
(10) Pub. No.: US 2009/0194846 A1
(43) Pub. Date: Aug. 6, 2009

(54) Fully Cu-metallized III-V group compound semiconductor device with palladium/germanium/copper ohmic contact system

(76) Inventors: Edward Yi CHANG, Baoshan Township (TW); Ke-Shian Chen, Taoyuan City (TW)

Correspondence Address: SINORICA, LLC, 2275 Research Blvd., Suite 500, ROCKVILLE, MD, 20850, US

(21) Appl. No.: 12/025,021

(22) Filed: Feb. 2, 2008

(51) Int. Cl. H01L 29/732

(52) U.S. Cl. 257/587; 257/E29.183; 257/E29.144

(57) ABSTRACT

The present invention discloses a fully Cu-metallized III-V group compound semiconductor device, wherein the fully Cu-metallized of a III-V group compound semiconductor device is realized via using an N-type gallium arsenide ohmic contact metal layer formed of a palladium/germanium/copper composite metal layer, a P-type gallium arsenide ohmic contact metal layer formed of a platinum/titanium/platinum/copper composite metal layer, and interconnect metals formed of a titanium/platinum/copper composite metal layer. Thereby, the fabrication cost of III-V group compound semiconductor devices can be greatly reduced, and the performance of III-V group compound semiconductor devices can be greatly promoted. Besides, the heat-dissipation effect can also be increased, and the electric impedance can also be reduced.

### BACKGROUND OF THE INVENTION

1. Field of the Invention

The present invention relates to a III-V group compound semiconductor element, particularly to a fully Cu-metallized III-V group compound semiconductor device with palladium/germanium/copper ohmic contact system.

2. Description of the Related Art

Traditional III-V group semiconductor elements, such as HBT (Heterojunction Bipolar Transistor), HEMT (High Electron Mobility Transistor) and MESFET (Metal Semiconductor Field Effect Transistor), adopt a gold/germanium/nickel composite layer as the ohmic contact metal layer and adopt gold as the material of interconnect metals. However, the gold/germanium/nickel ohmic contact metal layer has many weaknesses, such as too great an extension of the contact resistance, the indistinct contact border, and too high an annealing temperature.

In consideration of the RC delay effect, the elements can attain better performance via replacing gold with copper, which has lower resistance and better heat dissipation. Further, the cost thereof can be reduced also. Similar to the case that copper is used in silicon semiconductor elements, copper atoms will rapidly diffuse into a III-V group compound semiconductor element and thus disable the element if the ohmic contact metal layer and interconnect metals are made of copper.

Therefore, an effective diffusion barrier layer is eagerly desired in realizing a copper ohmic contact metal layer and a copper metal trace. In IEEE TRANSACTION ON ELECTRON DEVICE, VOL.51, NO.7, JULY 2004 was disclosed a conventional technology that WNx is used in a diffusion barrier layer for the copper metallization of interconnect metals in an InGaP—GaAs HBT. Refer to FIG. 1. However, gold is still used in the ohmic contact metal layers 42, 44 and 46 of the emitter, base and collector in the nGaP—GaAs HBT 40. Copper metallization is only partially realized in the conventional technology. Thus, the problems of using gold in ohmic contact metal layers still persist.

Accordingly, the present invention proposes a fully Cu-metallized III-V group compound semiconductor device with palladium/germanium/copper ohmic contact system to overcome the abovementioned problems.

### SUMMARY OF THE INVENTION

The primary objective of the present invention is provide a fully Cu-metallized III-V group compound semiconductor device with palladium/germanium/copper ohmic contact system, wherein the fully Cu-Metallized III-V group compound semiconductor device is realized via using a palladium/germanium/copper composite metal layer as the N-type gallium arsenide ohmic contact metal layer, a platinum/titanium/platinum/copper composite metal layer as the P-type gallium arsenide ohmic contact metal layer, and a titanium/platinum/copper composite metal layer as the interconnect metals.

Another objective of the present invention is provide a fully Cu-metallized III-V group compound semiconductor device with palladium/germanium/copper ohmic contact system to greatly reduce the fabrication cost of a III-V group compound semiconductor device and effectively promote the performance of a III-V group compound semiconductor device.

Further objective of the present invention is provide an fully Cu-metallized III-V group compound semiconductor device with palladium/germanium/copper ohmic contact system, wherein copper is used to reduce electric impedance and promote heat-dissipation effect.

To achieve the abovementioned objectives, the present invention proposes a fully Cu-metallized III-V group compound semiconductor device with palladium/germanium/copper ohmic contact system, which comprises: a compound semiconductor device, wherein the compound semiconductor device further comprises: at least one N-type gallium arsenide layer, and at least one P-type gallium arsenide layer; at least one N-type gallium arsenide ohmic contact metal layer formed of a palladium/germanium/copper composite layer and formed on the N-type gallium arsenide layer of the compound semiconductor device; a P-type gallium arsenide ohmic contact metal layer formed of a platinum/titanium/platinum/copper composite layer and formed on the P-type gallium arsenide layer of the compound semiconductor device; a passivation layer formed over the compound semiconductor device, the N-type gallium arsenide ohmic contact metal layer formed of a palladium/germanium/copper composite layer and the P-type gallium arsenide ohmic contact metal layer formed of a platinum/titanium/platinum/copper composite layer, having several openings revealing a portion of each of the N-type gallium arsenide ohmic contact metal layer formed of a palladium/germanium/copper composite layer and the P-type gallium arsenide ohmic contact metal layer formed of a platinum/titanium/platinum/copper composite layer; a plurality of interconnect metals formed of a titanium/platinum/copper composite layer and connected with the opening-revealed portions of the N-type gallium arsenide ohmic contact metal layer formed of a palladium/germanium/copper composite layer and P-type gallium arsenide ohmic contact metal layer formed of a platinum/titanium/platinum/copper composite layer.

Below, the embodiments are described in detail to make easily understood the objectives, technical contents, characteristics and accomplishments of the present invention.

### BRIEF DESCRIPTION OF THE DRAWINGS

FIG. 1 is a diagram schematically showing the structure of a conventional InGaP—GaAs HBT using copper as interconnect metal; and
FIG. 2 is a diagram schematically showing the structure of an overall copper metallization InGaP—GaAs HBT according to the present invention.

### DETAILED DESCRIPTION OF THE INVENTION

The spirit of the present invention is to propose device constituents to overall realize copper ohmic contact metal layers and copper interconnect metals in III-V group compound semiconductor devices, such as HBT, HEMT and MESFET. Below, the embodiment of the copper metallization in an InGaP—GaAs HBT is used to exemplify the present invention. However, the present invention is not limited to the embodiment.

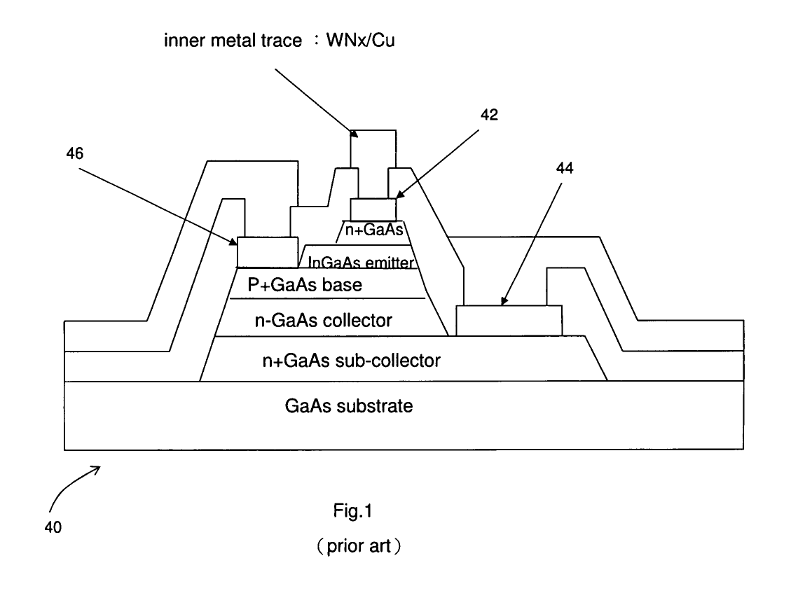

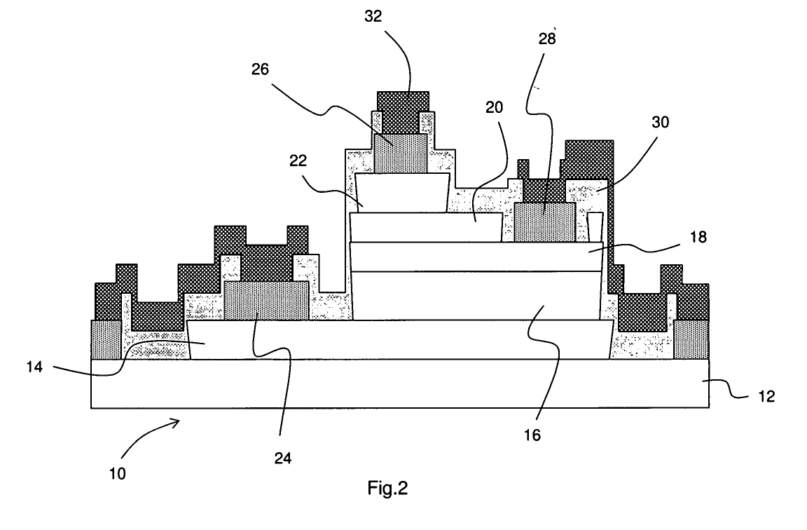

Refer to FIG. 2 a diagram schematically showing the structure of a fully Cu-metallized III-V group compound semiconductor device with palladium/germanium/copper ohmic contact system according to the present invention, wherein an InGaP—GaAs HBT is used to exemplify the structure thereof. The compound semiconductor device 10 comprises: a GaAs (Gallium Arsenide) substrate 12, an n⁺-GaAs collector 14, an n⁻-GaAs sub-collector 16, a p⁺-GaAs base 18, an n⁻-InGaP emitter 20 and a GaAs cap layer 22, wherein the n⁺-GaAs collector 14, n⁻-GaAs sub-collector 16, p⁺-GaAs base 18, n⁻-InGaP emitter 20 and GaAs cap layer 22 are sequentially bottom-up formed above the GaAs substrate 12.

The compound semiconductor device 10 further comprises: a collector ohmic contact metal layer 24 formed on the collector 14 and formed of a palladium/germanium/copper composite metal layer, an emitter ohmic contact metal layer 26 formed over the emitter 20 and formed of a palladium/germanium/copper composite metal layer, a base ohmic contact metal layer 28 formed on the base 18 and formed of a platinum/titanium/platinum/copper composite metal layer.

The compound semiconductor device 10 further comprises a passivation layer 30 formed over the compound semiconductor device 10, the collector ohmic contact metal layer 24, the emitter ohmic contact metal layer 26, and the base ohmic contact metal layer 28. The passivation layer 30 is used to separate the compound semiconductor device 10, and the ohmic contact metal layers 24, 26 and 28 from the air lest they deteriorate. The passivation layer 30 has several openings to reveal a portion of each of the ohmic contact metal layers 24, 26 and 28 and define connection sites for interconnect metals. The passivation layer 30 is made of silicon oxide or silicon nitride.

The compound semiconductor device 10 further comprises several inner metal trace layers 32 formed of a titanium/platinum/copper composite layer and formed on the openings revealing a portion of each of the collector ohmic contact metal layer 24, the emitter ohmic contact metal layer 26, and the base ohmic contact metal layer 28, wherein platinum functions as a diffusion barrier in the composite layer. Thus, the copper metallization layers completely replaces the traditional gold/germanium/nickel composite layers to function as ohmic contact metal layers in the compound semiconductor devcie 10.

All the abovementioned collector ohmic contact metal layer 24, emitter ohmic contact metal layer 26, base ohmic contact metal layer 28, and inner metal trace layers 32 may be fabricated with an electron beam vapor deposition method; the patterns thereof may be defined with a lift-off technology used in the traditional compound semiconductor device.

Compounds of Cu₃Ge and PdGaₓAs_{y} will form in the palladium/germanium/copper composite metal layer during annealing, and the formation of Cu₃Ge will exhaust the copper atoms in the palladium/germanium/copper composite metal layer. Thus, copper atoms will not diffuse to the GaAs compound semiconductor. Therefore, when the collector ohmic contact metal layer or emitter ohmic contact metal layer formed of the palladium/germanium/copper composite metal layer is applied to an N-type GaAs semiconductor device, the contact resistance of the collector or emitter ohmic contact metal layer can be reduced to 5.73×10⁷ Ω-cm² via a wider annealing temperature range of between 220 and 350° C. The compound Cu₃Ge has a lower chemical potential than Ga. Thus, Ga atoms will diffuse from the GaAs substrate to the ohmic contact metal layer to create an ohmic behavior. Besides, the palladium layer can increase the adhesion force of the germanium/copper layer lest the germanium/copper layer peel off.

In conclusion, the present invention proposes a fully Cu-metallized III-V group compound semiconductor device, wherein the Cu-metallized is overall realized in a III-V group compound semiconductor device via an N-type gallium arsenide ohmic contact metal layer formed of a palladium/germanium/copper composite metal layer, a P-type gallium arsenide ohmic contact metal layer formed of a platinum/titanium/platinum/copper composite metal layer, and interconnect metals formed of a titanium/platinum/copper composite metal layer, whereby the fabrication cost of III-V group compound semiconductor devices can be greatly reduced, and the performance of III-V group compound semiconductor devices can be greatly promoted. As the thermal conductivity of copper is higher than that of gold, the heat-dissipation effect can be increased, and the electric impedance can be reduced.

The preferred embodiments described above are only to exemplify the present invention but not to limit the scope of the present invention. Any equivalent modification or variation according to the scope of the spirit or characteristics of the present invention is to be also included within the scope of the present invention.

What is claimed is:

1. An fully Cu-metallized III-V group compound semiconductor device with palladium/germanium/copper ohmic contact system, comprising:
a compound semiconductor device further comprising:
at least one N-type gallium arsenide layer; and
at least one P-type gallium arsenide layer;
at least one N-type gallium arsenide ohmic contact metal layer formed of a palladium/germanium/copper composite layer and formed on said N-type gallium arsenide layer;
at least one P-type gallium arsenide ohmic contact metal layer formed of a platinum/titanium/platinum/copper composite layer and formed on said P-type gallium arsenide layer;
a passivation layer formed over said compound semiconductor device, said N-type gallium arsenide ohmic contact metal layer formed of a palladium/germanium/copper composite layer and said P-type gallium arsenide ohmic contact metal layer formed of a platinum/titanium/platinum/copper composite layer, having several openings revealing a portion of each of said N-type gallium arsenide ohmic contact metal layer formed of a palladium/germanium/copper composite layer and said P-type gallium arsenide ohmic contact metal layer formed of a platinum/titanium/platinum/copper composite layer; and
a plurality of interconnect metals formed of a titanium/platinum/copper composite layer and connected with said N-type gallium arsenide ohmic contact metal layer formed of a palladium/germanium/copper composite layer and said P-type gallium arsenide ohmic contact metal layer formed of a platinum/titanium/platinum/copper composite layer.

2. The fully Cu-metallized III-V group compound semiconductor device with palladium/germanium/copper ohmic contact metal layers according to claim 1, wherein said compound semiconductor device is heterojunction bipolar transistor (HBT), high electron mobility transistor (HEMT),or metal semiconductor field effect transistor (MESFET).

3. The fully Cu-metallized III-V group compound semiconductor devcie with palladium/germanium/copper ohmic contact system according to claim 2, wherein when said compound semiconductor device is heterojunction bipolar transistor, said N-type gallium arsenide layers function as collector and emitter, and said P-type gallium arsenide layer functions as base.

4. The fully Cu-metallized III-V group compound semiconductor devcie with palladium/germanium/copper ohmic contact system according to claim 1, wherein said III-V group compound semiconductor is gallium arsenide.

5. The fully Cu-metallized III-V group compound semiconductor devcie with palladium/germanium/copper ohmic contact system according to claim 1, wherein said passivation layer is made of silicon oxide or silicon nitride.

6. The fully Cu-metallized III-V group compound semiconductor devcie with palladium/germanium/copper ohmic contact system according to claim 1, wherein an electron beam vapor deposition technology is used to fabricate said N-type gallium arsenide ohmic contact metal layer formed of palladium/germanium/copper composite layer, said P-type gallium arsenide ohmic contact metal layer formed of platinum/titanium/platinum/copper composite layer, and said interconnect metals.

7. The fully Cu-metallized III-V group compound semiconductor devcie with palladium/germanium/copper ohmic contact system according to claim 1, wherein lift-off technology is used to define patterns of said N-type gallium arsenide ohmic contact metal layer formed of palladium/germanium/copper composite layer, said P-type gallium arsenide ohmic contact metal layer formed of platinum/titanium/platinum/copper composite layer, and said interconnect metals.

8. The fully Cu-metallized III-V group compound semiconductor devcie with palladium/germanium/copper ohmic contact system according to claim 1, wherein said ohmic contact metal layer formed of palladium/germanium/copper composite layer and said ohmic contact metal layer formed of platinum/titanium/platinum/copper composite layer are annealed at temperature of between 220 and 350° C. to achieve a better contact resistance.
